(19) United States
(12) Patent Application Publication
(10) Pub. No.: US 2013/0069687 A1
(43) Pub. Date: Mar. 21, 2013

(54) SOLAR SIMULATOR AND SOLAR CELL INSPECTION DEVICE

(71) Applicants: Masanori Ooto, Higashiyamato-city (JP); Ryouichi Higashi, Higashiyamato-city (JP); Tetsuya Saito, Higashiyamato-city (JP)

(72) Inventors: Masanori Ooto, Higashiyamato-city (JP); Ryouichi Higashi, Higashiyamato-city (JP); Tetsuya Saito, Higashiyamato-city (JP)

(73) Assignee: FUJI ELECTRIC CO., LTD., Kawasaki-shi (JP)

(21) Appl. No.: 13/390,101

(22) PCT Filed: Feb. 14, 2011
(86) PCT No.: PCT/JP2011/052990

§ 371 Date: May 1, 2012

(30) Foreign Application Priority Data
Jun. 4, 2010 (JP) 2010-129209

(51) Int. Cl. G01R 31/26; F21V 9/02

(52) U.S. Cl. CPC G01R 31/26; F21V 9/02
USPC 324/761.01; 362/2

(57) ABSTRACT

A solar simulator having improved measurement precision, including an array of light emitters having point light emitters planarly arranged in a given range, an effective irradiated region spaced apart from a surface having the array thereon, and a portion which absorbs at least a part of light from a direction which passes through a gap between the individual point light emitters. In a preferred aspect, the light absorption portion includes an absorption surface disposed in at least a part of the gaps between the light emitters. In another preferred aspect, a translucent board holds the light emitters and has a translucent portion corresponding to at least a part of the gaps between the light emitters, and an absorption layer at a position for absorbing light from the direction which passes through the translucent portion.

### CROSS-REFERENCE TO RELATED APPLICATIONS

The present application is the national phase of PCT patent application PCT/JP2011/052990, filed on Feb. 14, 2011, which claims priority from Japanese patent application 2010-129209, filed on Jun. 4, 2010.

### FIELD OF THE INVENTION

The present invention relates to a solar simulator and a solar cell inspection device each for inspecting a solar cell. More specifically, the present invention relates to a solar simulator using an array of light emitters including point light emitters, and a solar cell inspection device using the solar simulator.

### BACKGROUND ART

Conventionally, in order to inspect photoelectric conversion characteristics of a produced solar cell, electrical output characteristics of the solar cell are measured while the solar cell is irradiated with predetermined light. In the measurement, there is used a light emitter device for irradiating the solar cell with light satisfying predetermined conditions, i.e., a solar simulator.

In the solar simulator, in order to generate irradiation light having a spectrum similar to that of sunlight, in many cases, a combination of a light emitting body such as, e.g., a xenon lamp or a halogen lamp with an appropriate filter is used as a light emitter. Particularly, in the solar simulator for inspecting mass-produced solar cells, in addition to the above spectrum, a light intensity on a light-receiving surface of the solar cell, i.e., irradiance is carefully equalized. This is because quality control of the mass-produced solar cell is conducted on the basis of measured photoelectric conversion characteristics, and hence the measurement result is compared or contrasted to those of other solar cells. Hereinafter, in the solar simulator, a surface irradiated with light for measuring the solar cell is referred to as an “irradiated surface” and, in the irradiated surface, the range where the light-receiving surface of the solar cell is assumed to be positioned is referred to as an “effective irradiated region”.

In the conventional solar simulator, in order to equalize the irradiance in the effective irradiated region, a diffusing optical system or an integrating optical system is disposed at any position between the light emitter and the irradiated surface. Each of these optical systems is an optical element for equalizing the irradiance in the effective irradiated region by diffusing or condensing light from the light emitter to control the direction of the light at some midpoint of the distance of propagation of the light. For example, when trying to equalize the irradiance according to the conventional method for the measurement of a large-area solar cell such as an integrated solar cell, it becomes necessary to increase the distance of propagation of the light in accordance with the size of the measurement target solar cell (solar cell to be measured). As a result, the solar simulator using the conventional method in which the large-area solar cell is irradiated at the equalized irradiance inevitably occupies a large space.

On the other hand, as the light emitter of the solar simulator, there is proposed the use of a plate-like light emitter unit in which solid-state light emitters such as a light emitting diode (LED) and the like are planarly arranged (for example, the Japanese Translation of PCT Application No. 2004-511918, and the Japanese Patent Application Laid-open No. 2004-281706). As in the proposals, when the plate-like light emitter unit is applied to the solar simulator, by arranging several plate-like light emitter units into the shape of arranged tiles, it becomes possible to easily enlarge the effective irradiated region. In the solar simulator using such plate-late light emitter unit, it is possible to reduce an optical path length from the light emitter to the irradiated surface to be shorter than that in the solar simulator using the xenon lamp or the halogen lamp. This is because, between the light emitter and the irradiated surface, a large-scale optical system for equalizing the irradiance is not required. Thus, when the plate-like light emitter unit is used, it becomes easy to cope with an increase in the size of the solar cell, and an advantage is also achieved that an increase in the size of the solar simulator itself is easily suppressed.

### SUMMARY OF THE INVENTION

However, in the solar simulator using the plate-like light emitter unit disclosed in each of the Japanese Translation of PCT Application No. 2004-511918 and Japanese Patent Application Laid-open No. 2004-281706, since a measurement result different from current/voltage characteristics of the solar cell measured by using a higher-precision small solar simulator is obtained, there are cases where errors occur. Such errors typically present a problem especially when the measurement results of several solar cells having different light reflectances are compared with each other. For example, it is assumed that two types of solar cells exhibiting the same photoelectric conversion characteristics in a normal situation are measured. Naturally in this case, when the photoelectric conversion characteristics of the measure solar cells are compared with each other, the measurement results should naturally match each other. However, when the solar simulator using the plate-like light emitter unit is used, in the case where, e.g., two solar cells exhibiting the same photoelectric conversion characteristics have different light reflectances, the measurement results which should match each other become different in some cases.

Another typical example in which the difference in the measurement result becomes apparent is the case where areas, i.e., sizes of several solar cells of the same type are changed, and their measurement results are compared with each other. That is, in the normal situation, from two solar cells of the same type of which only sizes are changed, current/voltage characteristics (I-V characteristics) reflecting only the difference in size thereof should be obtained. In the case in the normal situation, for example, the photoelectric conversion efficiencies of the solar cells have the same value. When the description is given by using a specific example, in the measurement results of the current/voltage characteristics of large-size and small-size solar cells which have the ratio between areas contributing to photoelectric conversion of 2:1, for example, the current values at each voltage should naturally have the ratio of 2:1 and the photoelectric conversion efficiencies calculated from the solar cells should have the same value. However, when the measurement results of two solar cells of which only sizes are changed by the actual solar simulator using the plate-like light emitter unit are compared with each other, the above-described result is not necessarily obtained. For example, there are cases where the current values do not reflect the area ratio correctly, and the photoelectric conversion efficiencies which should have the same value have different values. Hereinafter, a method in which several measurement results obtained from individual solar cells are compared with each other is referred to as “comparing”, and measurement for the purpose of comparing several individual solar cells is referred to as “comparison measurement”.

To cope with the above-described inconsistency in the result of the comparison measurement, there can be used countermeasures such as, e.g., the execution of the calibration of the solar simulator at each measurement of the solar cell having a different light reflectance or the execution of the calibration thereof for each size of the solar cell. However, when the measurement which frequently uses the calibration is performed, it becomes necessary to have the procedure for grasping the light reflectance or the size of each of measurement target solar cells in advance, and the operation and management of the measurement processing become complicated. Further, there can be used countermeasures in which, e.g., the solar simulator is prepared individually for each type or size of the solar cell to be measured, or the operational mode of one solar simulator is switched for each type or size thereof. However, such countermeasures require the use of a plurality of solar simulators, or cause additional problems such as the inconsistency in the measurement result between the solar simulators or between the operational modes and the like. Therefore, these countermeasures are not practical.

The present invention is intended to contribute to facilitation of quality control of produced solar cells by allowing a reduction in the inconsistency between the measurement results of the solar cells by the solar simulator employing the plate-like light emitter, and allowing photoelectric conversion characteristics of the solar cells of various types or sizes to be compared with each other.

The inventors of the present application found out that the above-described problem resulted from re-reflection of irradiation light. Herein, the re-reflection denotes a phenomenon in which a part of light emitted from the solar simulator toward the solar cell is reflected by the surface or the internal portion of the solar cell to invert its direction, returns to the solar simulator side, and is reflected by the solar simulator again to be emitted to the solar cell. Light by the re-reflection (hereinafter referred to as “re-reflected light”) becomes a part of the light emitted to the solar cell to be measured together with the light emitted by the plate-like light emitter unit through light emission. Accordingly, the solar cell to be measured utilizes the light including the re-reflected light for electric power generation. A detailed description is given of the situation of measurement of the current/voltage characteristics (I-V characteristics) in the case of the presence of the re-reflection.

First, a description is given of the case where measurement results of several solar cells having mutually different light reflectances are compared with each other. In this case, the reflectances of the solar cells themselves are different, and hence the intensity of the re-reflection takes different values for different solar cells. As a result, the irradiance of the light emitted to the solar cell differs from solar cell to solar cell so that it becomes difficult to compare the resultant measurement results. Note that the cause for the difference in the light reflectance of the solar cell includes not only the difference in the type of the solar cell but also, e.g., variations in the reflectance of mass-produced individual solar cells.

Next, a description is given of the case where the measurement results of several solar cells having mutually different sizes are compared with each other. The reason for the difficulty in the comparison between the measurement results in this case is that the difference in the size of the solar cell results in the difference in the influence of the re-reflection. That is, the central portion of the solar cell is influenced by the re-reflected light more strongly than the peripheral edge portion thereof. This is because no re-reflected light reaches the peripheral edge portion of the solar cell from the outside thereof, while the re-reflected light reaches the central portion thereof from all directions. Even when trying to compare the measurement results of the solar cells of different sizes, the difference in the relative ratio between the central portion and the peripheral edge portion results in the difference in the influence of the re-reflection so that it becomes difficult to compare the measurement results in the case of the presence of the re-reflection. Note that, in this paragraph, in order to simplify the description, the description is given based on the assumption that there is no light returning from the region of the effective irradiated region where the solar cell is not present to the solar simulator.

Thus, in the case where the re-reflection occurs in the measurement of the photoelectric conversion characteristics, even when some measurement result is obtained, it is not clear whether the measurement result directly reflects characteristics of the solar cell itself, or the measurement result is influenced by the difference in the light reflectance of the size thereof. Conversely, if the re-reflection can be prevented at somewhere in an optical path in the measurement using the solar simulator, the necessity to consider the influence of the re-reflection is obviated, and the measurement result becomes more reliable. Herein, in order to increase the permissible range of the light reflectance or the size for the solar cell as the measurement target, the countermeasures for preventing the re-reflection are preferably attained only by the solar simulator. As a result, the inventors of the present application carefully examined which element was involved in the re-reflection particularly in the solar simulator using the plate-like array of light emitters.

What the inventors pay attention to is the configuration of the plate-like array of light emitters itself which uses a large number of light emitters having minute light emitting bodies (hereinafter referred to as “point light emitters”). The array of light emitters using a large number of point light emitters is used also in general lighting equipment. In the case of such lighting use, there are cases where a light-reflective body is disposed between the point light emitters. The reason for this is to reduce the loss of light and utilize more light flux (or radiant flux). As the light-reflective body for this purpose, for example, a white diffuse reflection layer is used. Even when such light-reflective body is not used, in the general lighting equipment, for example, a metal layer of a wiring for driving the point light emitter is exposed in a gap between the point light emitters in many cases. However, the inventors of the present application found out that, when the configuration of the array of light emitters for such general lighting equipment was employed in the solar simulator for the measurement of the solar cell without any alteration, the configuration of the array of light emitters itself became the cause for the re-reflection. This is because the light-reflective body such as the white diffuse reflection layer or the metal layer produces the action of enhancing illumination efficiency and, at the same time reflects light returned from the solar cell back to the solar cell again.

In view of the foregoing, the inventors found out that the re-reflection in the solar simulator using the plate-like array of light emitters was suppressed by employing, on the contrary to the case of the general lighting equipment, an absorption portion for absorbing light, and achieved the invention of the present application.

That is, in an aspect of the present invention, there is provided a solar simulator including an array of light emitters having a plurality of point light emitters planarly arranged in a given range, an effective irradiated region which is disposed to be spaced apart from a surface having the point light emitters arranged thereon in the array of light emitters, receives light from the array of light emitters, and has a light-receiving surface of a target solar cell to be inspected disposed on at least a part thereof, and a light absorption portion, or light absorber, which absorbs at least a part of light from a direction of the effective irradiated region which passes through a gap between the individual point light emitters in the array of light emitters.

In the aspect of the present invention, the “array of light sources” denotes a light emitter set including several light emitters which are arranged in any manner. In addition, the “gap between the individual point light emitters” denotes all or a part of portions other than the point light emitter on the surface including the point light emitters, i.e., the surface of the array of light emitters. Note that the “point light emitter” denotes a light emitter which emits light in a minute region, and is not limited to a light emitter in which light is emitted only from a point in the sense of geometry. Further, “at least a part of light from a direction of the effective irradiated region” denotes any part of the light incident from the side of the effective irradiated region. The “part” mentioned herein denotes a part in terms of any viewpoint such as a part of a region on or through which light is incident or passes, a part of an angle range when light is incident in an incident direction in the angle range, or a part of a wavelength range (emission wavelength range) in an emission spectrum (radiation spectrum) of light.

According to any aspect of the present invention, by effectively suppressing the re-reflection, it becomes possible to prevent the irradiance of the irradiation light by the solar simulator from being changed depending on the light reflectance or the size of the solar cell to be measured, and perform the irradiation of the light using the solar simulator for measuring the photoelectric conversion characteristics of the solar cell with excellent controllability.

### BRIEF DESCRIPTION OF THE DRAWINGS

FIG. 1 is a perspective view showing a schematic configuration of a solar cell inspection device of an embodiment of the present invention;

FIG. 2 includes a schematic cross-sectional view (FIG. 2(a)) and a schematic plan view (FIG. 2(b)) showing a schematic configuration of a solar simulator in the solar cell inspection device of the embodiment of the present invention;

FIG. 3 is a cross-sectional view showing an enlarged array of light emitters in the embodiment of the present invention in which each of FIGS. 3(a) and 3(b) shows an example of a disposition of an absorption portion in the embodiment;

FIG. 4 is a plan view showing a typical array of point light emitters in a light emitter unit in the solar simulator in the embodiment of the present invention;

FIG. 5 is a plan view showing a typical array of the point light emitters in a light emitter unit in the solar simulator in the embodiment of the present invention;

FIG. 6 is a graph showing measurement results of a large-size solar cell and a small-size solar cell measured by a solar cell inspection device employing a conventional solar simulator in comparison with each other, and includes a current/voltage characteristic view (FIG. 6(a)) and electric power characteristics (FIG. 6(b)); and

FIG. 7 is a graph showing the measurement results of the large-size solar cell and the small-size solar cell measured by the solar cell inspection device employing the solar simulator in the embodiment of the present invention, and includes a current/voltage characteristic view (FIG. 7(a)) and electric power characteristics (FIG. 7(b)).

### DETAILED DESCRIPTION OF THE INVENTION

A description is given hereinbelow of embodiments of the present invention. In the following description, sections or elements common in all of the drawings are designated by common reference numerals unless otherwise specified. In addition, in the drawings, the individual elements of each embodiment are not necessarily shown with mutual scales maintained.

### First Embodiment

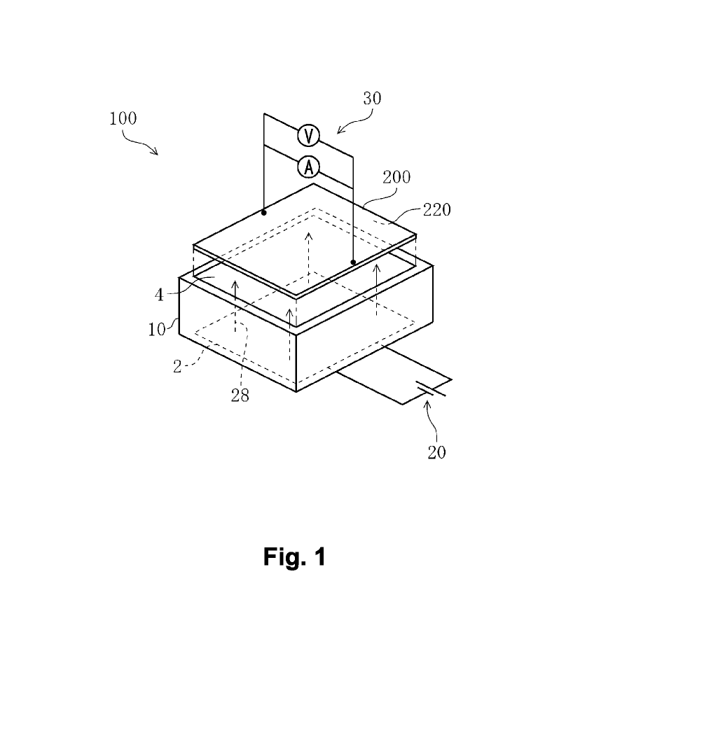

FIG. 1 is a perspective view showing a schematic configuration of a solar cell inspection device 100 of the present embodiment. The solar cell inspection device 100 of the present embodiment includes a solar simulator 10, a light quantity control section 20, and an electrical measurement section 30. The light quantity control section 20 is connected to the solar simulator 10, and controls the intensity of light 28 emitted by an array of light emitters 2 in the solar simulator 10. In addition, the electrical measurement section 30 is electrically connected to a solar cell to be measured 200 (hereinafter referred to as a “solar cell 200”), and measures current/voltage characteristics (I-V characteristics) while applying an electric load to the solar cell 200. The solar cell inspection device 100 emits the light 28 having a predetermined irradiance set by the solar simulator 10 to a light-receiving surface 220 of the solar cell 200 positioned on an effective irradiated region 4. From the current/voltage characteristics of the solar cell 200 measured by the electrical measurement section 30 in a state where the light is emitted, as numerical indicators for photoelectric conversion characteristics of the solar cell 200, numerical indicators such as, e.g., an open-circuit voltage value, a short-circuit current value, conversion efficiency, and a fill factor can be determined.

### [Configuration of Solar Simulator]

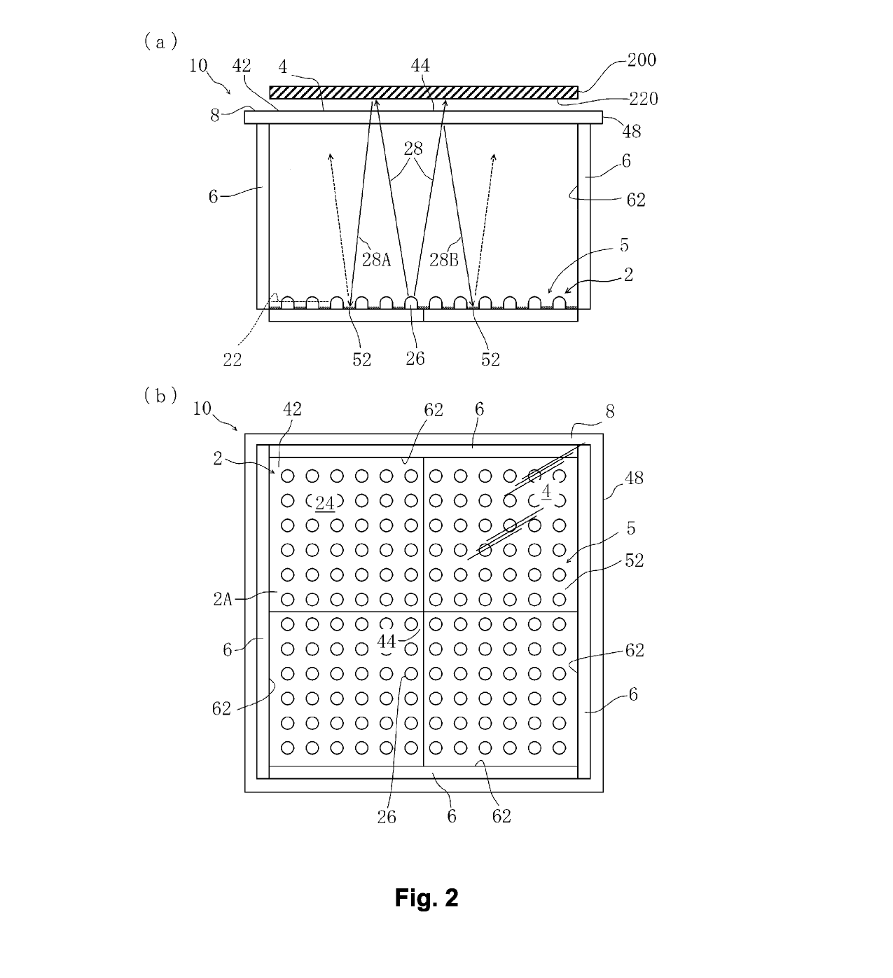

The configuration of the solar simulator 10 is further described. FIG. 2 includes a schematic cross-sectional view (FIG. 2(a)) and a schematic plan view (FIG. 2(b)) showing the schematic configuration of the solar simulator 10 of the solar cell inspection device 100 of the present embodiment. The schematic cross-sectional view (FIG. 2(a)) schematically shows the disposition of the solar cell 200. The solar simulator 10 includes the array of light emitters 2, and the effective irradiated region 4.

The effective irradiated region 4 is a part of an irradiated surface 8 disposed to be spaced apart from a light-emitting surface 22 of the array of light emitters 2, and denotes the range of the irradiated surface 8 on which the light-receiving surface 220 of the solar cell 200 is assumed to be positioned. Consequently, the effective irradiated region 4 serves as a region which receives the light 28 from the array of light emitters 2, and has the light-receiving surface 220 of the target solar cell 200 disposed on at least apart thereof. Note that, as the solar cell 200, those having various light reflectances and sizes are assumed. Consequently, the disposition of the solar cell 200 is such that the light-receiving surface 220 of the solar cell 200 is positioned on at least apart of the effective irradiated region 4 of the solar simulator 10. When the solar cell 200 is small in size, there is produced a region in the effective irradiated region 4 where the solar cell 200 is not disposed. In order to avoid influence on the measurement, such region is covered with a background plate (not shown) for absorbing light.

### [Array of Light Emitters]

The array of light emitters 2 includes a plurality of point light emitters 26 planarly arranged in the light-emitting surface 22 in a given range 24. The given range 24 of the array of light emitters 2 is, e.g., rectangular, and in the rectangular range 24, the point light emitters 26 are disposed in the array where they are vertically and horizontally arranged at a predetermined pitch. As shown in FIG. 2, it is possible to configure the array of light emitters 2 so as to be composed of, e.g., a set including one or more light emitter units 2A. The light emitter unit 2A in this case includes a plurality of the point light emitters 26 arranged on, e.g., a plate-like circuit board, and each point light emitter 26 is disposed and supported on the circuit board.

### [Absorption Layer]

In gaps between the point light emitters 26 of the array of light emitters 2, an absorption layer 52 is provided. When photoelectric conversion characteristics of the solar cell 200 are measured using the solar simulator 10, typically, reflected light may occur on the surface or the internal portion of the solar cell 200 and, e.g., upper and lower surfaces of a glass top plate 48. In FIG. 2(a), reflected light 28A reflected by the surface of the solar cell 200 and reflected light 28B reflected by the lower surface of the top plate 48 are shown as examples. Regardless of the causes for the reflected light, most of the reflected light 28A and 28B having returned to the side of the solar simulator 10 is absorbed by the absorption layer 52. As a result, the light out of the reflected light 28A and 28B which returns to the solar cell 200 again becomes extremely weak light as compared with the case where the absorption layer 52 is not used. Thus, it becomes possible to prevent or significantly reduce the occurrence of a phenomenon in which the light from the solar cell 200 is reflected again by the array of light emitters 2 and returns to the solar cell 200 to disturb the irradiance value.

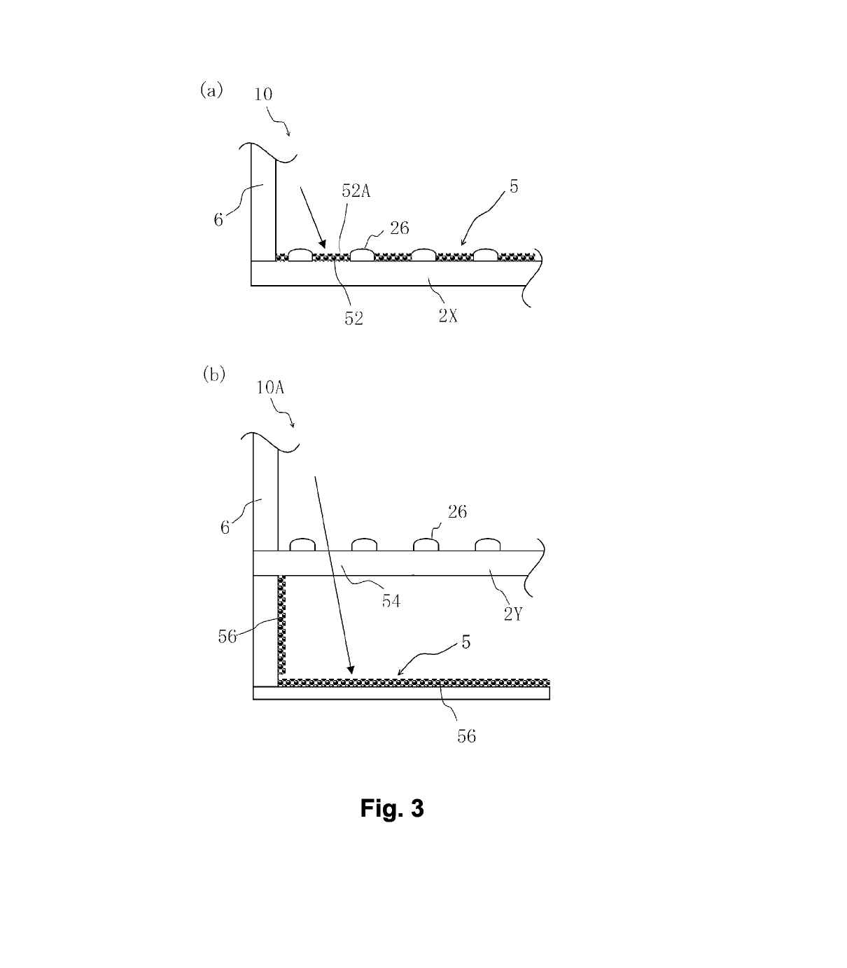

FIG. 3 is a cross-sectional view showing the enlarged array of light emitters 2 in the present embodiment, and FIG. 3(a) shows an example of a disposition of an absorption portion 5 in the present embodiment. As shown in FIG. 3(a), the absorption portion 5 in the solar simulator 10 in the present embodiment is configured such that the absorption layer 52 is disposed at the portion of a board 2X on which the point light emitters 26 are arranged, the portion being a portion where the point light emitter 26 is not arranged. The surface of the absorption layer 52 on the side of the effective irradiated region 4 serves as an absorption surface 52A disposed in at least a part of gaps between the individual point light emitters 26. Note that the degree of the light having returned to the side of the solar simulator 10 absorbed by the absorption layer 52 is dependent on various factors. The factors include the degree of the light reflectance of the absorption layer 52, and the degree of the proportion of the area of the gaps between the individual point light emitters 26 occupied by the absorption layer 52.

The absorption layer 52 employed as the absorption portion 5 of the solar simulator 10 of the present embodiment is any layer including the absorption surface 52A which absorbs at least a part of the light incident thereon from the side of the effective irradiated region 4. A material which can be used to form the absorption layer 52 is a substance exhibiting high light absorption properties as the quality thereof, and a specific example thereof includes an absorptive coating containing carbon black. Typical examples of the absorption layer 52 other than this include a surface treated layer in which the light absorption properties are imparted to the surface of a board by etching or the like, a layer to which a light-absorptive cloth (for example, a black velvet cloth or the like) is bonded, and a layer to which a light-absorptive film is bonded. In order to sufficiently obtain the effect of reflection prevention by light absorption, the material preferable as the absorption layer 52 is a material having high absorption coefficient in the wavelength range of the electric power generation sensitivity of the solar cell or in the emission wavelength range of the irradiation light. The absorption surface 52A of the absorption layer 52 is disposed so as to fill in at least a part of, preferably all of the gaps between the individual point light emitters 26.

[Modification: Disposition with Different Absorption Layer]

In this connection, in the present embodiment, the configuration of the absorption portion 5 for suppressing the re-reflection is not limited to the absorption layer 52 disposed on the surface of the board 2X of the light emitter unit on the side of the effective irradiated region 4. A description is given of the configuration having another absorption portion 5 in the present embodiment as a modification. FIG. 3(b) shows the configuration of a solar simulator 10A of the modification in which the absorption portion 5 is modified in the present embodiment. In the solar simulator 10A of the modification, as shown in FIG. 3(b), as the board 2Y for the light emitter unit, a board formed of a translucent material is employed. In this case, a portion corresponding to at least a part of the gaps between the individual point light emitters 26 serves as a translucent portion 54. Light having passed through the translucent portion 54 is emitted toward the back of the board 2Y as viewed form the effective irradiated region 4. At the back of the board 2Y, there is disposed an absorption layer 56 for absorbing the light having passed through the board 2Y at a proper position as the absorption portion 5. More specifically, in FIG. 3(b), the space at the back of the board 2Y is covered with a plate material, and the absorption layer 56 is disposed on the inner surface thereof to function as the absorption portion 5. Similarly to the absorption layer 52 described in connection with FIG. 3(a), the absorption layer 56 can be formed of various materials exhibiting the light absorption properties. Consequently, most of the light having passed through the gaps between the individual point light emitters 26 is absorbed by the absorption layer 56, and the quantity of the light travelling toward the solar cell again becomes extremely small.

Note that, in the configuration of the solar simulator 10A of the modification, at the portion corresponding to the gap between the individual point light emitters 26, some opaque element other than the translucent portion 54 may also be disposed. That is, the configuration of an electrical wiring or the like needed for a lighting operation of the point light emitter 26 is not required to have translucency. On the surface of such opaque element on the solar cell side, an absorption portion (not shown) preferably formed of the light-absorptive material is provided to suppress the re-reflection.

In the solar simulator 10A of the modification, more preferably, one or both of the surfaces of the board 2Y is subjected to reflection prevention processing. The reflection prevention processing is typically carried out by disposing a reflection preventing film on the surface of the board 2Y. Such reflection prevention processing functions so as to reduce surface reflection of the light passing through the translucent portion 54 on the surface of the board 2Y. In this configuration, the light is prevented from being reflected by the surface reflection when the light passes through the board 2Y and entering into the solar cell 200 again. The reflection prevention processing in this case includes any processing which can reduce the surface reflection in the translucent portion 54 of the board 2Y to a sufficiently low reflectance in the wavelength range of the electric power generation sensitivity of the solar cell 200 or in the emission wavelength range of the light to be emitted. When the reflection prevention processing is based on the reflection preventing film, a typical example of the reflection preventing film is what is called an AR coating (anti reflection coating). Other than this, as the reflection preventing film, there can be employed any reflection prevention film such as, e.g., a reflection preventing film in which a low refractive index layer is disposed, a layer formed with minute irregularities on a submicron scale, or the like.

### [Reflection Mirror]

A description is given again of the solar simulator 10 in FIGS. 2 and 3(a). Preferably, the solar simulator 10 further includes a reflection mirror 6. This reflection mirrors 6 are disposed so as to surround a given range 24 of the array of light emitters 2. The specific disposition of the reflection mirrors 6 is typically as follows. First of all, the array of light emitters 2 has a plurality of point light emitters 26 which are arranged so as to be planarly scattered over the given range 24. The given range 24 is a spread surface including the point light emitters 26, i.e., a planar region of the light-emitting surface 22 in the given range where the point light emitters 26 are arranged. Herein, there is assumed a pillar-like solid body having one of the given range 24 of the array of light emitters 2 and the effective irradiated region 4 which are disposed as described above as its upper surface and having the other one thereof as the bottom surface. The reflection mirrors 6 are disposed at positions on the side surfaces of the pillar-like solid body. For example, as shown in FIG. 2, when both of the given range 24 of the array of light emitters 2 and the effective irradiated region 4 are in the same rectangular shape, the given range 24 of the array of light emitters 2, the effective irradiated region 4, and the reflection mirrors 6 form a quadrangular prism, and the mirrors 6 are disposed at positions on the side surfaces of the quadrangular prism. Note that, in the typical example shown in FIG. 2, the given range 24 of the array of light emitters 2 is formed in the same shape as that of the corresponding effective irradiated region 4. In addition, the effective irradiated region 4 and the light-emitting surface 22 of the array of light emitters 2 make a pair of surfaces which are spaced apart from each other in parallel with each other, and the reflection mirrors 6 are vertically oriented relative to the effective irradiated region 4 and the light-emitting surface 22 of the array of light emitters. Here, the expected function of each of the reflection mirrors 6 is a function of preventing the lowering of the irradiance in a vicinity of a peripheral edge portion 42 of the effective irradiated region 4 compared with the central portion 44. Therefore, the reflection function of the reflection mirror 6 is typically provided to surfaces 62 on the side of the effective irradiated region 4 in the reflection mirror 6, i.e., the surfaces 62 of the reflection mirrors 6 oriented inward in FIG. 2(b).

As the reflection mirror 6, a mirror having a sufficient reflectance in an emission wavelength range of the light emitter is selected. For example, there are used a metal reflection mirror in which a metal is formed into a layer on a substrate made of glass or the like, and a dielectric multilayer film reflection mirror in which a dielectric thin film is formed on the substrate as a multilayer film. The reflectance of the reflection mirror 6 is preferably as high as possible.

The solar cell 200 is disposed such that the light-receiving surface 220 is directed to the array of light emitters 2 of the solar simulator 10. Specifically, the solar cell 200 in the disposition of the solar simulator 10 of FIG. 2 is placed on, e.g., the upper surface of a glass top plate 48, and directs the light-receiving surface 220 downward in the paper sheet of FIG. 2(a). In this disposition, the light 28 for illumination is emitted toward the light-receiving surface 220 from below in FIG. 2(a).

For the top plate 48 of the solar simulator 10 shown in FIG. 2(a), a member allowing light to transmit therethrough such as a glass plate material is used. In this case, of both surfaces of the top plate 48 disposed in spaced apart relation so as to correspond to the light-emitting surface 22 of the array of light emitters 2, the effective irradiated region 4 is a part of the irradiated surface 8 serving as the upper surface in the orientation of FIG. 2(a). Accordingly, for example, the effective irradiated region 4 in the case where the top plate 48 is made of glass receives the light from the array of light emitters 2 in the lower portion of FIG. 2(a) through the top plate 48. That is, the effective irradiated region 4 is defined as a part of the irradiated surface 8 directing its front surface upward in the paper sheet of FIG. 2(a), and receives the light from below. Note that, in FIG. 2(a), the solar simulator 10 is drawn in its orientation in which the light 28 is emitted from below in the drawing. However, the disposition of the solar simulator 10 and the direction of emission of the light 28 are not particularly limited. In other words, the solar simulator 10 may be disposed such that the orientation of the solar simulator 10 is any orientation and the direction of emission of the light 28 is any direction, for example, the direction of emission of the light 28 is sideward or downward. In these cases, the top plate 48 described above is not required so that the effective irradiated region is defined by other modes. For example, when the direction of emission of the light 28 is sideward, the surface of the solar cell includes a vertical direction so that the effective irradiated region is defined by the range of an opening as an example. In addition, when the direction of emission of the light is downward, the solar cell is supported from below by a support plate with the light-receiving surface faced upward and the surface opposite to the light-receiving surface faced downward. The effective irradiated region in this case is defined by, e.g., the range of the surface of the support plate supporting the solar cell.

In the present embodiment, as each point light emitter 26 in the array of light emitters 2, a solid state light emitter (solid state light emitting element) such as a light emitting diode (LED) or the like can be used. The light emission mode of the point light emitter 26 employing the light emitting diode is not particularly limited. That is, it is possible to employ the light emitting diode having, e.g., a single color light emission mode with the emission spectrum concentrated in a narrow wavelength range. Other than this, by using the light emitting diode in which a phosphor and a single color light emitting chip are integrated, it is possible to also employ the solid state light emitter having the light emission mode providing the wider emission spectrum.

Preferably, all of the point light emitters 26 included in the array of light emitters 2 are light emitters having the same light emission mode. That is, for example, when the light emitter is the light emitting diode, it is preferable to employ the light emitting diodes of the same type which are produced so as to exhibit the same emission spectrum for all of the point light emitters 26. This is because, when the array of light emitters 2 is produced by, e.g., employing several types of the light emitting diodes having different emission wavelengths in a mixed manner, the irradiance distribution in the effective irradiated region differs depending on the wavelength range. By contrast, when the light emitting diodes of the same type which are produced so as to exhibit the same emission spectrum are used, the irradiance distribution in the effective irradiated region becomes almost identical at any wavelength in the emission spectrum. This is because the wavelength dependence of each point light emitter 26 is suppressed.

Note that what is available as the point light emitter 26 of the present embodiment includes various light emitters such as a halogen lamp, a xenon lamp, and a metal halide lamp in addition to the light emitting diode. In addition, in the solar simulator 10 for the solar cell inspection device 100, by arranging a plurality of the light emitter units 2A into the shape of arranged tiles as the array of light emitters 2, it is possible to easily enlarge the area of the array of light emitters 2, i.e., the effective irradiated region 4. In the solar simulator 10 shown in FIG. 1, the four light emitter units 2A are disposed in the shape of arranged tiles.

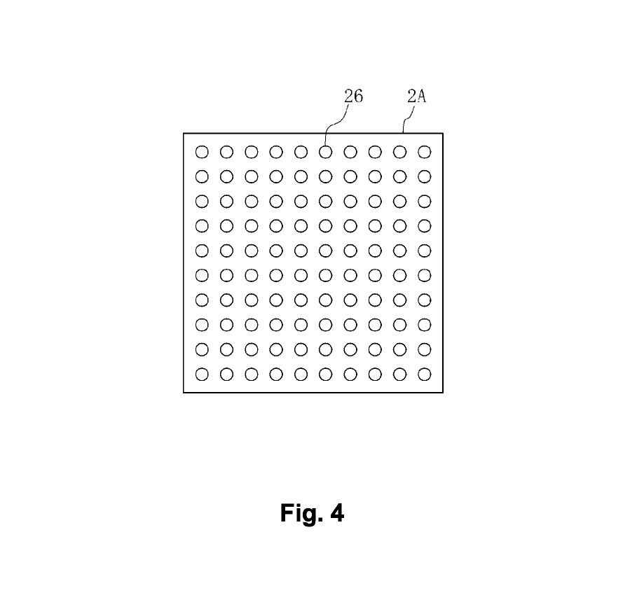

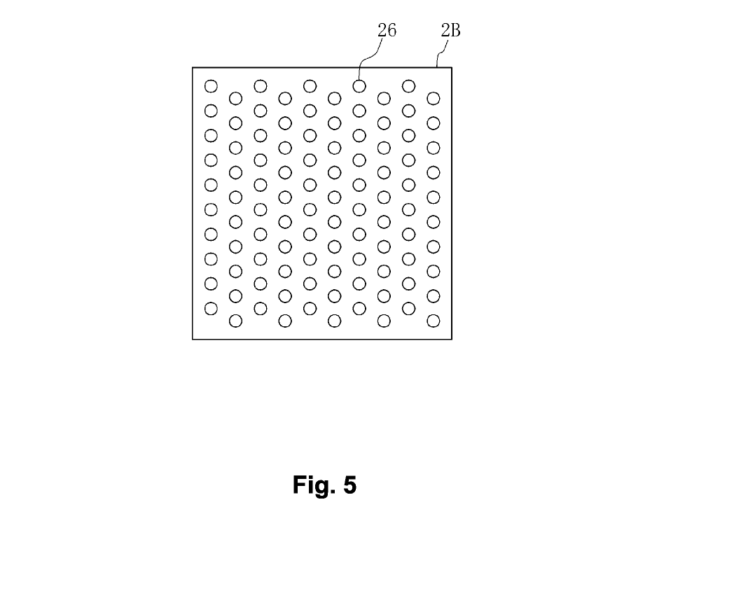

FIG. 3 is a plan view showing the typical array of the point light emitters 26 in each light emitter unit 2A in the solar simulator 10 in the present embodiment. The point light emitters 26 used in the solar simulator 10 of the present embodiment are arranged in a lattice shape, and the individual point light emitters 26 are placed at positions (lattice points) having regularity. As a result, also in the light emitter unit 2A, the point light emitters 26 have a lattice array pattern. The array pattern may have a triangular lattice in addition to a tetragonal lattice as in FIG. 4. FIG. 5 is a plan view showing the typical array of the point light emitters 26 in a light emitter unit 2B of a modification employing the triangular lattice. In the present embodiment, other than these arrays, it is also possible to use, e.g., a honeycomb-lattice array pattern (not shown).

### [Measurement Example]

A description is given hereinbelow of Comparative Example of measurement and Example of measurement of the measurement (comparison measurement) in which two solar cells of the same type having different sizes are compared with each other by using the solar cell inspection device 100 employing the solar simulator 10 having the configuration shown in FIG. 3(a). Herein, in Comparative Example of measurement, the above comparison measurement is performed by using the measurement of a conventional solar simulator, while in Example of measurement, the above comparison measurement is performed by using the measurement of the solar simulator 10 of the present embodiment.

### [Comparative Example of Measurement]

In Comparative Example of measurement, photoelectric conversion characteristics of the solar cell were measured by using a solar cell inspection device (a “conventional solar cell inspection device”) employing a solar simulator without the absorption layer 52 (hereinafter referred to as a “conventional solar simulator”) in the solar simulator 10 having the configuration shown in FIG. 3(a). As measured items, current/voltage characteristics (I-V characteristics) were measured, and an electric power value obtained by multiplying a current value by a voltage value was also determined at each voltage. In the measurement, in order to perform the comparison measurement on the measurement result based on the difference in the size of the solar cell, as the measurement target, the solar cell covering 100% of the area of the effective irradiated region and the solar cell covering only 50% of the area thereof were used. Hereinafter, the solar cell covering 100% of the area of the effective irradiated region and the solar cell covering 50% thereof are referred to as a large-size solar cell and a small-size solar cell, respectively. Note that, as for the area of the region contributing to the photoelectric conversion, the area of the small-size solar cell was just ½ of that of the large-size solar cell. In addition, in graphs of the measurement results shown below, in order to facilitate the comparison of the measurement results, values in the measurement result of the large-size solar cell are shown as they are, while in the measurement result of the small-size solar cell, the current value and the electric power value are doubled and shown.

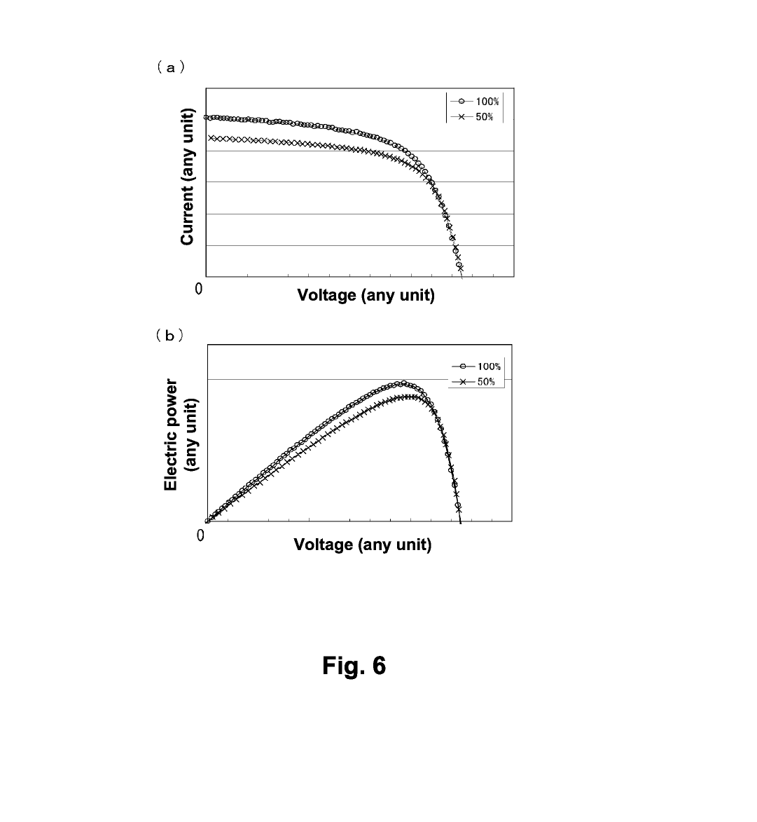

FIG. 6 is a graph showing the measurement results of the large-size solar cell and the small-size solar cell measured by the conventional solar cell inspection device in comparison with each other. FIGS. 6(a) and 6(b) are graphs showing current/voltage characteristics and electric power characteristics measured by the same conventional solar cell inspection device. In each graph, the measurement results of the large-size solar cell and the small-size solar cell are indicated by marks labeled with “100%” and “50%”.

FIG. 6(a) shows the current value in the large-size solar cell and the value obtained by doubling the current value in the small-size solar cell at each voltage. As seen from the graph in FIG. 6(a), the current value of the large-size solar cell is larger than the value obtained by doubling the current value in the small-size solar cell. As indicators for comparison, when attention is paid to the current value (short-circuit current) at the load voltage of 0 volt, when the value obtained by doubling the current value in the small-size solar cell is assumed to be 100%, the current value in the large-size solar cell is the value corresponding to 114.5%. In addition, as shown in FIG. 6(b), also in the electric power at each voltage, the value in the large-size solar cell is larger than the value obtained by doubling the value in the small-size solar cell. In particular, at the maximum electric power (maximum output), when the value obtained by doubling the value in the small-size solar cell is assumed to be 100%, the value in the large-size solar cell is the value corresponding to 111.4%.

Thus, when the current/voltage characteristics and the electric power characteristics are compared between the solar cells having different sizes, in Comparative Example of measurement using the conventional solar cell inspection device, the current and electric power values do not reflect the size of the solar cell correctly. In this connection, when the photoelectric conversion efficiency for each of the large-size and small-size solar cells is calculated in this Comparative Example of measurement, as the ratio between the photoelectric conversion efficiency of the large-size solar cell and that of the small-size solar cell, the value corresponding to the ratio between the maximum outputs thereof is calculated. That is, although the same photoelectric conversion efficiency should be naturally obtained from the solar cells of the same type, the photoelectric conversion efficiency determined from the large-size solar cell is the value corresponding to about 111% when the value of the small-size solar cell is assumed to be 100%.

### [Example of Measurement]

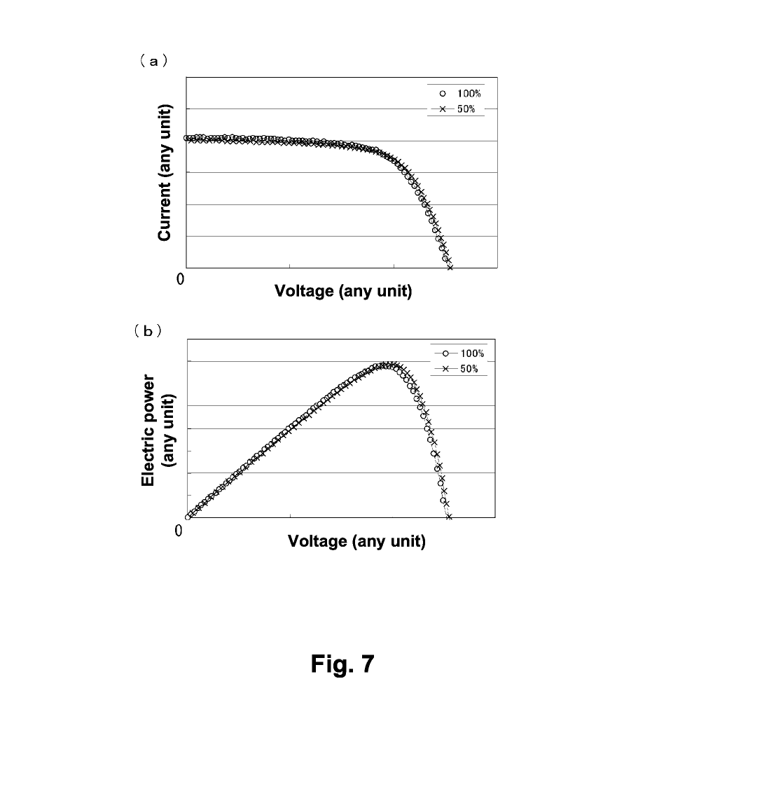

Next, as Example of measurement of the present embodiment, the measurement similar to that of Comparative Example of measurement was performed by using the solar cell inspection device 100 (FIG. 1) employing the solar simulator 10 having the configuration shown in FIG. 3(a). The result is shown in FIG. 7. As the measured items, the same as those in Comparative Example of measurement shown in FIG. 6 were measured. In addition, as the measurement target large-size and small-size solar cells, the same solar cells as those in Comparative Example of measurement were used.

FIG. 7 is a graph showing the measurement results of the large-size and small-size solar cells measured by the solar cell inspection device 100 employing the solar simulator 10 in the present embodiment, and FIGS. 7(a) and 7(b) show the current/voltage characteristics and the electric power characteristics measured by the same solar cell inspection device 100, respectively.

As shown in FIG. 7(a), as for the current value at each voltage, the value in the large-size solar cell is measured as the value approximate to the value obtained by doubling the value in the small-size solar cell. Specifically, as for the short-circuit current, when the value obtained by doubling the value in the small-size solar cell is assumed to be 100%, the value in the large-size solar cell corresponds to 102.0%. In addition, as shown in FIG. 7(b), as for the electric power at each voltage as well, the value in the large-size solar cell almost matches the value obtained by doubling the value in the small-size solar cell. In terms of the maximum output value, the value of the large-size solar cell when the value obtained by doubling the value in the small-size solar cell is assumed to be 100% corresponded to 100.6%. Note that the measured values of the I-V characteristics of the large-size and small-size solar cells obtained by the solar cell inspection device 100 matched those obtained by a high-precision small solar simulator employing a light emitter serving as reference sunlight.

Thus, in Example of measurement using the solar cell inspection device 100 employing the solar simulator 10 of the embodiment of the present invention, in comparison with Comparative Example of measurement using the conventional solar simulator, the measurement which does not depend on the size of the solar cell was allowed. That is, by providing the absorption layer 52, the configuration of the solar simulator employing the plate-like array of light emitters which does not require the consideration of the difference in the influence of the re-reflection resulting from the difference in the size of the solar cell was implemented. Note that, also in the case of the comparison measurement with the solar cells of different light reflectances as the measurement targets, similarly to the case of the solar cells of different sizes, the measurement by the solar cell inspection device 100 employing the solar simulator 10 provided with the absorption layer 52 is effective. This is because the re-reflection in the solar simulator 10 is effectively prevented so that the influence on the irradiance of the irradiation light is lessened even when the light reflectances are different.

As described above, in the present embodiment, it becomes possible to provide the solar simulator in which the re-reflection is reduced, and by extension it becomes possible to avoid the difficulty in the comparison between the measurement results of the solar cells resulting from the dependence of the measurement result of the photoelectric conversion characteristics of the solar cell on the light reflectance or the size of the measurement target solar cell.

Thus, the embodiments of the present invention have been specifically described. The above-described embodiments and Example of measurement are described for the purpose of explaining the invention, and the scope of the invention of the present application should be defined on the basis of the description of the scope of claims. In addition, modifications within the scope of the present invention including other combinations of the individual embodiments are also included in the scope of claims.

According to the present invention, there is provided a solar simulator or a solar cell inspection device in which the light reflectance or the size of a solar cell is less likely to influence measurement precision and high-precision measurement is thereby allowed. As a result, it becomes possible to perform the inspection of the solar cell in the production step of producing the solar cells of various types or various areas with excellent precision. Such an improvement in the inspection precision contributes to the production of the high-quality solar cell, and also contributes to the spread of any electric power equipment or electric equipment which includes such solar cell as a part thereof.

1. A solar simulator comprising:
an array of light emitters having a plurality of point light emitters arranged in a plane in a given range,
wherein light from the array of light emitters is incident upon an effective irradiated region spaced laterally apart from the given region of the plane, and at least a part of the effective radiated region corresponds to a light receiving surface of a target solar cell to be inspected; and
a light absorber that absorbs light originating from the array of emitters redirected from the effective irradiated region and passing through gaps between the individual point light emitters of the array of light emitters.

2. The solar simulator according to claim 1, wherein the light absorber is an absorption layer having an absorption surface disposed in said gaps.

3. The solar simulator according to claim 1, further comprising:
a translucent board which holds the plurality of point light emitters and has a translucent portion corresponding to said gaps, wherein the light absorber is provided at positions to absorb light having passed through the translucent portion from the effective irradiated region.

4. The solar simulator according to claim 3, wherein a reflection preventing film is provided on at least one of a front surface and a back surface of the translucent board, which allows the light in the translucent portion to pass therethrough.

5. The solar simulator according to claim 1, further comprising: a reflection mirror which is disposed so as to surround the given range of the array of light emitters.

6. The solar simulator according to claim 1, wherein each of the point light emitters is a light emitting diode selected from a group consisting of a single color light emitting diode and a light emitting diode in which a phosphor and a single color light emitting chip are integrated.

7. The solar simulator according to claim 1, wherein each of the point light emitters is a lamp selected from a group consisting of a halogen lamp, a xenon lamp, and a metal halide lamp.

8. A solar cell inspection device comprising:
the solar simulator according to claim 1, further comprising:
a light quantity control section which is connected to the solar simulator to control a quantity of light emitted by the array of light emitters; and
an electrical measurement section which is electrically connected to the target solar cell to measure a photoelectric conversion characteristic thereof while applying an electric load thereto.
